(19) United States
(12) Patent Application Publication
(10) Pub. No.: US 2023/0393205 A1
(43) Pub. Date: Dec. 7, 2023

(54) COMPUTER PROGRAM, DETERMINING DEVICE, AND DETERMINING METHOD

(71) Applicant: GS Yuasa International Ltd., Kyoto-shi, Kyoto (JP)

(72) Inventors: Masaki OYA, Kyoto-shi, Kyoto (JP); Yu MATSUMOTO, Kyoto-shi, Kyoto (JP); Shinichi NAMITOKO, Kyoto-shi, Kyoto (JP); Seiji TAKAI, Kyoto-shi, Kyoto (JP); Eiji HAYASHI, Kyoto-shi, Kyoto (JP)

(21) Appl. No.: 18/247,356

(22) PCT Filed: Sep. 22, 2021
(86) PCT No.: PCT/JP2021/034747

§ 371 Date: Mar. 30, 2023

(30) Foreign Application Priority Data
Oct. 1, 2020 (JP) 2020-167186
Oct. 1, 2020 (JP) 2020-167187

(51) Int. Cl. G01R 31/367; G01R 31/00

(52) U.S. Cl. CPC G01R 31/367; G01R 31/006

(57) ABSTRACT

Provided are a computer program, a determination device, and a determination method. A computer is caused to execute a process of estimating a state of at least one of an energy storage device and a charge system by executing a simulation using a battery model for simulating the energy storage device and a charge system model for simulating the charge system that charges the energy storage device and determining the compatibility between the energy storage device and the charge system based on the estimated state.

### CROSS REFERENCE TO RELATED APPLICATIONS

This application is a National Stage Application, filed under 35 U.S.C. § 371, of International Application No. PCT/JP2021/034747, filed Sep. 22, 2021, which international application claims priority to and the benefit of Japanese Application No. 2020-167187, filed Oct. 1, 2020; and Japanese Application No. 2020-167186, filed Oct. 1, 2020; the contents of all of which as are hereby incorporated by reference in their entireties.

### BACKGROUND

### Technical Field

The present invention relates to a computer program, a determination device, and a determination method.

### Description of Related Art

A battery and a charge-discharge system for charging and discharging the battery are mounted on a vehicle such as an electric vehicle (EV) or a hybrid electric vehicle (HEV) (see, for example, Patent Document JP-A-2011-062018).

Such a charge-discharge system acquires various types of information such as a battery temperature, a state of charge (SOC), a state of health (SOH), a voltage, and a current from a battery management unit (BMU) and executes charge-discharge control based on the acquired various types of information.

### BRIEF SUMMARY

When the specification of the charge-discharge system included in the vehicle and the performance of the battery mounted on the vehicle do not match, there is a possibility that excessive power is supplied to the battery or the time required for charging becomes very long. There is also a possibility that the performance of the battery is not sufficiently exerted or the deterioration of the battery is accelerated. If such a mismatch is found at the stage of comprehensive verification of the vehicle system in which the battery is actually mounted, the manufacturer needs to review the specifications of the charge-discharge system or needs to change the type of battery mounted on the vehicle, thus causing a problem that the agreement of specifications cannot be reached early.

An object of the present invention is to provide a computer program, a determination method, and a determination device which determine the compatibility between a charge-discharge system and an energy storage device by simulation.

A computer program causes a computer to execute a process of estimating the behavior of charge control for an energy storage device by executing a simulation using a battery model for simulating the energy storage device and a charge system model for simulating the charge system that charges the energy storage device and determining the compatibility between the energy storage device and the charge system based on the estimated behavior of charge control.

A computer program causes a computer to execute a process of estimating the state of at least one of an energy storage device and a power management system by executing a simulation using a battery model for simulating the energy storage device and a charge-discharge system model for simulating the power management system for the energy storage device and determining the compatibility between the energy storage device and the power management system based on the estimated state of the energy storage device.

A determination device includes an estimation unit that estimates the behavior of charge control for an energy storage device by executing a simulation using a battery model for simulating the energy storage device and a charge system model for simulating the charge system that charges the energy storage device and a determination unit that determines the compatibility between the energy storage device and the charge system based on the estimated behavior of charge control.

A determination device includes an estimation unit that estimates the state of at least one of an energy storage device and a power management system by executing a simulation using a battery model for simulating the energy storage device and a charge-discharge system model for simulating the power management system for the energy storage device and a determination unit that determines the compatibility between the energy storage device and the power management system based on the estimated state of the energy storage device.

A determination method, by using a computer, estimates the behavior of charge control for an energy storage device by executing a simulation using a battery model for simulating the energy storage device and a charge system model for simulating the charge system that charges the energy storage device and determines the compatibility between the energy storage device and the charge system based on the estimated behavior of charge control.

A determination method, by using a computer, estimates the state of at least one of an energy storage device and a power management system by executing a simulation using a battery model for simulating the energy storage device and a charge-discharge system model for simulating the power management system for the energy storage device and determines compatibility between the energy storage device and the power management system based on the estimated state of the energy storage device.

According to the present application, compatibility between the charge-discharge system and the energy storage device can be determined by simulation.

### BRIEF DESCRIPTION OF THE FIGURES

FIG. 1 is a block diagram illustrating the configuration of a control system in a vehicle.

FIG. 2 is a block diagram illustrating the internal configuration of an energy storage device.

FIG. 3 is a block diagram illustrating the internal configuration of the development support device according to a first embodiment.

FIG. 4 is a block diagram illustrating the configuration of a simulation model used by the development support device.

FIG. 5 is a circuit diagram illustrating an outline of a battery model.

FIG. 6A is a graph illustrating simulation results of a charge voltage and a battery voltage.

FIG. 6B is a graph illustrating simulation results of a charge voltage and a battery voltage.

FIG. 7A is a graph illustrating a simulation result of an applied current to an energy storage device.

FIG. 7B is a graph illustrating a simulation result of an applied current to an energy storage device.

FIG. 8 is a flowchart illustrating a procedure of processing executed by the development support device.

FIG. 9 is a block diagram illustrating the configuration of a control system in a vehicle.

FIG. 10 is a block diagram illustrating the internal configuration of the development support device according to a second embodiment.

FIG. 11 is a block diagram illustrating the configuration of a simulation model used by the development support device.

FIG. 12 is a schematic diagram illustrating an example of a parameter setting screen in a battery model.

FIG. 13 is a schematic diagram illustrating an example of a parameter setting screen in a charge-discharge system model.

FIG. 14 is a flowchart illustrating a procedure of processing executed by the development support device.

FIG. 15 is a schematic diagram illustrating a display example of a simulation execution result.

### DETAILED DESCRIPTION OF VARIOUS EMBODIMENTS

A computer program according to an embodiment causes a computer to execute a process of estimating the state of at least one of an energy storage device and a charge system by executing a simulation using a battery model for simulating the energy storage device and a charge system model for simulating the charge system that charges the energy storage device and determining the compatibility between the energy storage device and the charge system based on the estimated state.

When the internal structure is changed in designing an energy storage device, or when the composition of the active material or the electrolyte solution is changed, the characteristics of the battery change. When the characteristics of the battery change, it is necessary to change the charge control according to a change in the characteristics. In an energy storage device, overcharge and overdischarge must be avoided, and the importance of charge control is high. As in the present embodiment, when the compatibility between the energy storage device and the charge system is determined by simulation using a model, a battery charger that generates a high voltage in charge control is unnecessary, and safety is high. In verification using an actual machine or a prototype, it is necessary to charge an actual battery, and thus it takes time to obtain the determination result of compatibility. However, in the case of determination by simulation, it is not necessary to charge the battery, and thus the determination result of compatibility can be quickly obtained. Considering the recent remarkable development progress of electric vehicles, renewable energy, smart grids, and the like, expectations for high-performance and high-safety energy storage devices are great, and there is a great significance of the shortening of safety design and development time utilizing simulation.

In the computer program, the state estimated by the simulation may include a temporal change in charge system voltage determined according to the state of the energy storage device and a temporal change in battery voltage that is a voltage across both terminals of the energy storage device. The computer may be caused to execute the process of determining the compatibility between the energy storage device and the charge system based on the difference between the charge system voltage and the battery voltage. In verification using an actual machine or a prototype, when the voltage difference between the charge system voltage and the battery voltage increases, a current entering the battery may become more than allowable, and the safety cannot be guaranteed. On the other hand, in the present embodiment, since compatibility is determined by simulation using a model, safety can be guaranteed even under a situation in which an excessive current flows.

In the computer program, the state estimated by the simulation may include a temporal change in applied current applied to the energy storage device at the time of charging, and the computer may be caused to execute the process of determining compatibility between the energy storage device and the charge system based on the difference between the applied current and an allowable value set for the applied current. In verification using an actual machine or a prototype, a current entering the battery may become more than allowable, and the safety cannot be guaranteed. On the other hand, in the present embodiment, since compatibility is determined by simulation using a model, safety can be guaranteed even under a situation in which an excessive current flows.

In the computer program, the charge system model may be set using a transfer function representing the relationship between a control input and a control output in the charge system. In verification using an actual machine or a prototype, a delay may occur between a control input and a control output in the charge system. For example, when it takes time to drop the voltage to a target value, an excessive current flows through a battery, so that safety cannot be guaranteed. On the other hand, when it takes time to increase the voltage to the target value, it takes time to charge the battery, and there is a possibility that a power shortage state continues for a long time. On the other hand, in the present embodiment, since the transfer function is set in the charge system model and the compatibility between the energy storage device and the charge system is determined by simulation, for example, safety can be guaranteed even under a situation in which an allowable current or more flows, and the determination result of the compatibility can be quickly obtained even under a situation in which the charge time continues for a long time in an actual machine or a prototype.

In the computer program, the charge system model may simulate a control delay in the charge system. In verification using an actual machine or a prototype, a delay may occur between a control input and a control output in the charge system. For example, when it takes time to drop the voltage to a target value, an excessive current flows through a battery, so that safety cannot be guaranteed. When it takes time to increase the voltage to the target value, there is a possibility that a power shortage state continues for a long time. On the other hand, in the present embodiment, since the transfer function is set in the charge system model and the compatibility between the energy storage device and the charge system is determined by simulation, for example, safety can be guaranteed even under a situation in which an allowable current or more flows. In an actual machine or a prototype, even when the time required for charging is long, a compatibility determination result can be quickly obtained.

In the computer program, the battery model may include an equivalent circuit of the energy storage device. According to this configuration, since the equivalent circuit of the energy storage device is used, safety can be guaranteed even under a situation in which an allowable current or more flows in an actual machine or a prototype.

A computer program according to an embodiment causes a computer to execute a process of estimating a state of at least one of an energy storage device and a power management system by executing a simulation using a battery model for simulating the energy storage device and a charge-discharge system model for simulating a power management system for the energy storage device and determining the compatibility between the energy storage device and the power management system based on the estimated state of the energy storage device.

When the internal structure is changed in designing an energy storage device, or when the composition of the active material or the electrolyte solution is changed, the characteristics of the battery change. When the characteristics of the battery change, it is necessary to change the charge-discharge control according to a change in the characteristics. In an energy storage device, overcharge and overdischarge must be avoided, and the importance of charge-discharge control is high. As in the present embodiment, when the compatibility between the energy storage device and the power management system is determined by simulation using a model, a battery charger that generates a high voltage in charge control is unnecessary, and safety is high. In the present embodiment, an entire power system including a battery such as a 12 V or 48 V battery, regenerative power, solar power generation, a 100 V power supply, a power conditioner (power control), and an energy storage system incorporating a reused battery is referred to as a power management system. In verification using an actual machine or a prototype, it is necessary to charge and discharge an actual battery, and thus it takes time to obtain the determination result of compatibility. However, in the case of determination by simulation, it is not necessary to charge and discharge the battery, and thus the determination result of compatibility can be quickly obtained. Considering the recent remarkable development progress of electric vehicles, renewable energy, smart grids, and the like, expectations for high-performance and high-safety energy storage devices are great, and there is a great significance of the shortening of safety design and development time utilizing simulation.

In the computer program, the battery model may include a state estimation model for estimating at least one of the SOC, SOH, voltage, current, and temperature of the energy storage device, a component model for simulating a component constituting the energy storage device, a charge-discharge control model for simulating charge-discharge control for the energy storage device, and an event estimation model for estimating at least one of deterioration and heat generation of the energy storage device. In verification using an actual machine or a prototype, when the compatibility between the energy storage device and the power management system is determined, it is necessary to repeat charging and discharging of the actual battery by variously changing a setting value in the power management system, and it takes time to obtain a determination result. When the determination result that the compatibility is low is obtained, it is necessary to change the combination of the energy storage device and the power management system and continue the verification, and it takes more time. On the other hand, in the present embodiment, since compatibility can be determined for various combinations of the energy storage device and the power management system by variously changing the parameters of the power management system prepared as the model, a determination result of compatibility can be quickly obtained. Even when a determination result indicating that the compatibility is low is obtained, it becomes clear which part of the specification should be changed, and thus providing an effective development support tool.

In the computer program, the charge-discharge system model may be a model including at least one of efficiency, resistance, a rotational speed, a predetermined voltage, and a voltage control characteristic in the power management system as a parameter. In verification using an actual machine or a prototype, when the compatibility between the energy storage device and the power management system is determined, it is necessary to repeat charging and discharging of the actual battery by variously changing a setting value in the power management system, and it takes time to obtain a determination result. When the determination result that the compatibility is low is obtained, it is necessary to change the combination of the energy storage device and the power management system and continue the verification, and it takes more time. On the other hand, in the present embodiment, since compatibility can be determined for various combinations of the energy storage device and the power management system by variously changing the parameters of the power management system prepared as the model, a determination result of compatibility can be quickly obtained. Even when a determination result indicating that the compatibility is low is obtained, it becomes clear which part of the specification should be changed, and thus providing an effective development support tool.

In the computer program, the computer may be caused to execute a process of receiving an input of a parameter indicating the initial state of each model. According to this configuration, since simulation can be executed with an arbitrary state of the energy storage device and the power management system as an initial state, it is possible to shorten the time required for determining compatibility as compared with a verification method using an actual machine or a prototype that needs to determine compatibility by charging and discharging an actual battery.

In the computer program, the computer may be caused to execute a process of causing a display device to display an estimation result by each model. According to this configuration, for example, since it is possible to display the temporal transition of the parameter obtained by executing a simulation, it is possible to clarify which part should be changed in the specification when a determination result indicating that the compatibility is low is obtained.

A determination device according to an embodiment includes an estimation unit that estimates the state of at least one of an energy storage device and a charge system by executing a simulation using a battery model for simulating the energy storage device and a charge system model for simulating a charge system that charges the energy storage device and a determination unit that determines the compatibility between the energy storage device and the charge system based on the estimated state.

When the internal structure is changed in designing an energy storage device, or when the composition of the active material or the electrolyte solution is changed, the characteristics of the battery change. When the characteristics of the battery change, it is necessary to change the charge control according to a change in the characteristics. In an energy storage device, overcharge and overdischarge must be avoided, and the importance of charge control is high. As in the case of the determination device according to the present embodiment, when the compatibility between the energy storage device and the charge system is determined by simulation using a model, a battery charger that generates a high voltage in charge control is unnecessary, and safety is high. In verification using an actual machine or a prototype, it is necessary to charge an actual battery, and thus it takes time to obtain the determination result of compatibility. However, in the case of determination using the determination device by simulation, it is not necessary to charge the battery, and thus the determination result of compatibility can be quickly obtained. Considering the recent remarkable development progress of electric vehicles, renewable energy, smart grids, and the like, expectations for high-performance and high-safety energy storage devices are great, and there is a great significance of the shortening of safety design and development time utilizing simulation.

A determination device according to an embodiment includes an estimation unit that estimates the state of at least one of an energy storage device and a power management system by executing a simulation using a battery model for simulating the energy storage device and a charge-discharge system model for simulating the power management system for the energy storage device and a determination unit that determines the compatibility between the energy storage device and the power management system based on the estimated state of the energy storage device.

When the internal structure is changed in designing an energy storage device, or when the composition of the active material or the electrolyte solution is changed, the characteristics of the battery change. When the characteristics of the battery change, it is necessary to change the charge-discharge control according to a change in the characteristics. In an energy storage device, overcharge and overdischarge must be avoided, and the importance of charge-discharge control is high. As in the case of the determination device according to the present embodiment, when the compatibility between the energy storage device and the power management system is determined by simulation using a model, a battery charger that generates a high voltage in charge control is unnecessary, and safety is high. In the present embodiment, an entire power system including a battery such as a 12 V or 48 V battery, regenerative power, solar power generation, a 100 V power supply, a power conditioner (power control), and an energy storage system incorporating a reused battery is referred to as a power management system. In verification using an actual machine or a prototype, it is necessary to charge and discharge an actual battery, and thus it takes time to obtain the determination result of compatibility. However, in the case of determination using the determination device by simulation, it is not necessary to charge and discharge the battery, and thus the determination result of compatibility can be quickly obtained. Considering the recent remarkable development progress of electric vehicles, renewable energy, smart grids, and the like, expectations for high-performance and high-safety energy storage devices are great, and there is a great significance of the shortening of safety design and development time utilizing simulation.

A determination method according to an embodiment, by using a computer, estimates the state of at least one of an energy storage device and a charge system by executing a simulation using a battery model for simulating the energy storage device and a charge system model for simulating a charge system that charges the energy storage device and determines the compatibility between the energy storage device and the charge system based on the behavior of the estimated state.

When the internal structure is changed in designing an energy storage device, or when the composition of the active material or the electrolyte solution is changed, the characteristics of the battery change. When the characteristics of the battery change, it is necessary to change the charge control according to a change in the characteristics. In an energy storage device, overcharge and overdischarge must be avoided, and the importance of charge control is high. As in the case of the determination method according to the present embodiment, when the compatibility between the energy storage device and the charge system is determined by simulation using a model, a battery charger that generates a high voltage in charge control is unnecessary, and safety is high. In verification using an actual machine or a prototype, it is necessary to charge an actual battery, and thus it takes time to obtain the determination result of compatibility. However, in the case of determination using the computer by simulation, it is not necessary to charge the battery, and thus the determination result of compatibility can be quickly obtained. Considering the recent remarkable development progress of electric vehicles, renewable energy, smart grids, and the like, expectations for high-performance and high-safety energy storage devices are great, and there is a great significance of the shortening of safety design and development time utilizing simulation.

A determination method according to an embodiment, by using a computer, estimates the state of at least one of an energy storage device and a power management system by executing a simulation using a battery model for simulating the energy storage device and a charge-discharge system model for simulating the power management system for the energy storage device and determines compatibility between the energy storage device and the power management system based on the estimated state of the energy storage device.

When the internal structure is changed in designing an energy storage device, or when the composition of the active material or the electrolyte solution is changed, the characteristics of the battery change. When the characteristics of the battery change, it is necessary to change the charge-discharge control according to a change in the characteristics. In an energy storage device, overcharge and overdischarge must be avoided, and the importance of charge-discharge control is high. As in the case of the determination method according to the present embodiment, when the compatibility between the energy storage device and the power management system is determined by simulation using a model, a battery charger that generates a high voltage in charge control is unnecessary, and safety is high. In the present embodiment, an entire power system including a battery such as a 12 V or 48 V battery, regenerative power, solar power generation, a 100 V power supply, a power conditioner (power control), and an energy storage system incorporating a reused battery is referred to as a power management system. In verification using an actual machine or a prototype, it is necessary to charge and discharge an actual battery, and thus it takes time to obtain the determination result of compatibility. However, in the case of determination using the computer by simulation, it is not necessary to charge and discharge the battery, and thus the determination result of compatibility can be quickly obtained. Considering the recent remarkable development progress of electric vehicles, renewable energy, smart grids, and the like, expectations for high-performance and high-safety energy storage devices are great, and there is a great significance of the shortening of safety design and development time utilizing simulation.

The first embodiment will exemplify a case in which the present invention is applied to a charge system mounted on a vehicle such as a hybrid electric vehicle (HEV) or an electric vehicle (EV).

### First Embodiment

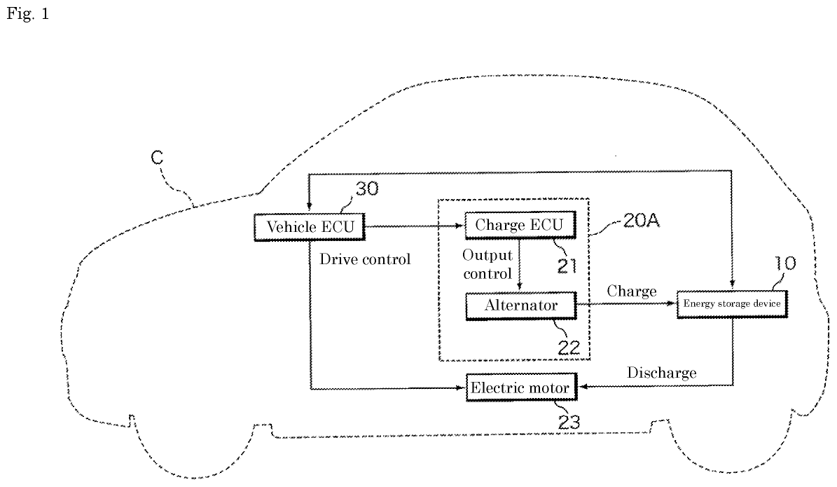

FIG. 1 is a block diagram illustrating the configuration of a control system in a vehicle. A vehicle C includes, as the components of a control system, an energy storage device 10, a charge system 20A for charging the energy storage device 10, and a vehicle electronic control unit (ECU) 30 that executes control of the entire vehicle. The energy storage device 10, the charge system 20A, and the vehicle ECU 30 are communicably connected to each other via an in-vehicle line such as a controller area network (CAN) or a local interconnect network (LIN). In the embodiment, the vehicle ECU 30 monitors the traveling state of the vehicle C, the charge state of the energy storage device 10, and the like and executes control or the like for switching charging and discharging of the energy storage device 10 according to the traveling state of the vehicle C and the charge state of the energy storage device 10.

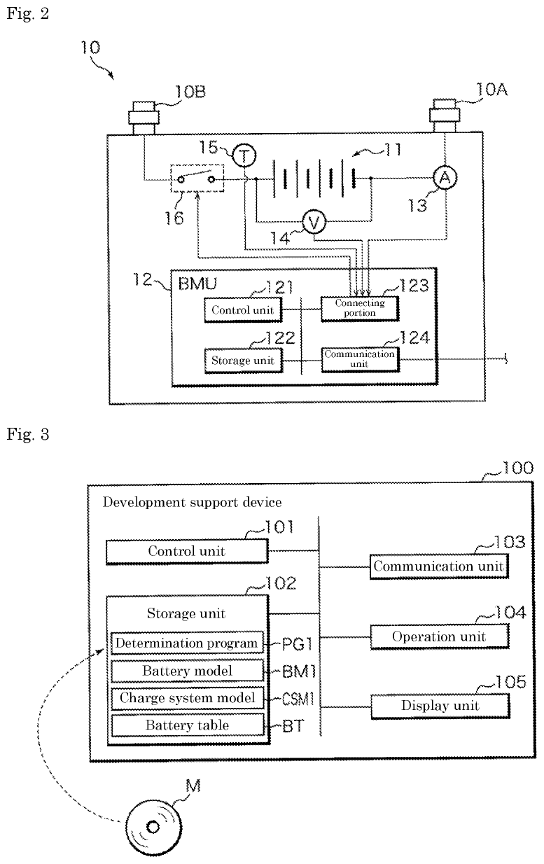

The energy storage device 10 includes an energy storage device 11 and a battery management unit (BMU) 12 (see FIG. 2). The energy storage device 11 includes, for example, an assembled battery formed by connecting a plurality of batteries in series. The energy storage device 11 included in the energy storage device 10 is charged by power supplied from the charge system 20A of the vehicle C and supplies power to a load in response to a control command from the vehicle ECU 30. An example of the load to which the energy storage device 10 supplies power is an electric motor 23 that generates a drive torque for causing the vehicle C to travel. Other examples of the load include various accessories included in the vehicle C, such as a headlight, a turn signal lamp, an in-vehicle lamp, and a power window. The BMU 12 has a function of managing the energy storage device 10. The BMU 12 has a function of estimating the state of the energy storage device 10, a function of detecting abnormality in the energy storage device 10, and the like and notifies the vehicle ECU 30 of information regarding the estimated state (for example, SOC) of the energy storage device 10, information regarding the detected abnormality, and the like.

The charge system 20A includes a charge ECU 21 and an alternator 22. The alternator 22 is a generator coupled to the output shaft of an engine (not illustrated) and is configured to generate power by the rotation of the output shaft. The power obtained by the power generation of the alternator 22 is supplied to the loads included in the energy storage device 10 and the vehicle C under the control of the charge ECU 21. The alternator 22 performs regenerative control to generate power when the vehicle C is decelerating, thereby applying a braking force to the vehicle C as a load with respect to the rotation of the engine output shaft, and supplying the generated power to the loads provided in the energy storage device 10 and the vehicle C.

FIG. 2 is a block diagram illustrating the internal configuration of energy storage device 10. The energy storage device 10 includes a current sensor 13, a voltage sensor 14, a temperature sensor 15, and a relay 16 in addition to the energy storage device 11 and the BMU 12. The energy storage device 11 includes, for example, a plurality of lithium ion secondary batteries connected in series.

The current sensor 13 is provided between the energy storage device 11 and a negative electrode terminal 10A and measures a current flowing into the energy storage device 11. The current sensor 13 outputs a measurement result to the BMU 12.

The voltage sensor 14 is connected in parallel to the energy storage device 11 and measures a voltage across both ends of the energy storage device 11. The voltage sensor 14 outputs a measurement result to the BMU 12.

The temperature sensor 15 is provided inside or outside the energy storage device 10 and measures a temperature. A plurality of temperature sensors 15 may be provided. The temperature measured by the temperature sensor 15 is, for example, the temperature of the energy storage device 11. In this case, the temperature sensor 15 is provided near the energy storage device 11 (inside the energy storage device). The temperature measured by the temperature sensor 15 may be a temperature of an environment (environmental temperature) in which the energy storage device 10 is installed. In this case, the temperature sensor 15 is provided near the energy storage device 10. In the following description, the temperature of the energy storage device 11 is referred to as the temperature of the energy storage device 10 without distinguishing the temperature of the energy storage device from the environmental temperature. The temperature sensor 15 outputs a measurement result to the BMU 12.

The relay 16 is provided between the energy storage device 11 and a positive electrode terminal 10B and is a circuit element for cutting off or connecting a charge-discharge path of the energy storage device 11 according to a control command from the BMU 12. When the energy storage device 10 normally functions, the charge-discharge path is connected, and the energy storage device 11 can be charged from the outside, and power can be supplied (discharged) from the energy storage device 11 to the load. On the other hand, when any abnormality is detected in the energy storage device 10, the charge-discharge path is cut off by a control command from the BMU 12, and the charge of the energy storage device 11 and the power supply (discharge) to the load are stopped.

In the embodiment, the relay 16 is an example of a circuit element for cutting off or connecting the charge-discharge path. Alternatively, the charge-discharge path may be cut off or connected using a semiconductor switch such as a field-effect transistor (FET).

The BMU 12 is an apparatus for managing the state of the energy storage device 10 and includes, for example, a control unit 121, a storage unit 122, a connecting portion 123, and a communication unit 124. The control unit 121 includes a central processing unit (CPU), a read only memory (ROM), and a random access memory (RAM). The CPU included in the control unit 121 executes a control program stored in advance in the ROM to implement a function of estimating the state of the energy storage device 10, a function of detecting an abnormality in the energy storage device 10, and the like. The RAM temporarily stores various types of information generated during the execution of calculation by the CPU. The storage unit 122 includes an electronically erasable programmable read only memory (EEPROM) and stores data necessary for control and the like. The current sensor 13, the voltage sensor 14, the temperature sensor 15, the relay 16, and the like are connected to the connecting portion 123. The communication unit 124 is communicably connected to the vehicle ECU 30 via an in-vehicle line such as CAN or LIN.

The control unit 121 of the BMU 12 acquires the current value measured by the current sensor 13, the voltage value measured by the voltage sensor 14, and the temperature measured by the temperature sensor 15 via the connecting portion 123 and calculates the SOC and the target value of the charge voltage of the energy storage device 10 based on these data. The control unit 121 notifies the vehicle ECU 30 of the calculated SOC and the target value of a charge voltage via the communication unit 124. For example, when the temperature measured by the temperature sensor 15 exceeds a preset threshold, the control unit 121 determines that an abnormality in the energy storage device 10 has been detected and outputs a control command to cut off the charge-discharge path to the relay 16.

In the embodiment, the energy storage device 10 is configured to incorporate the BMU 12. Alternatively, the BMU 12 may be provided outside the energy storage device 10.

The charge system 20A mounted on the vehicle C is developed and manufactured by, for example, a vehicle manufacturer, and the energy storage device 10 is developed and manufactured by, for example, a battery manufacturer. When the charge control specification of the charge system 20A mounted on the vehicle C and the performance of the energy storage device 10 incorporated in the vehicle C do not match, there is a possibility that excessive power is supplied to the energy storage device 10 or the time required for charging becomes very long. In a case in which the above-described defect is found at a point of time when the energy storage device 10 is incorporated in the vehicle C and the entire vehicle is comprehensively verified, it is necessary to review the charge control specification of the charge system 20A, or it is necessary to change the type of the energy storage device 10 incorporated in the vehicle C. Therefore, the agreement of the specification cannot be reached at an early stage.

According to the embodiment, in a computer (a development support device 100 illustrated in FIG. 3) independent of the vehicle C, a simulation using a model simulating the energy storage device 10 and a model simulating the charge system 20A of the vehicle C is executed, and the compatibility between the energy storage device 10 mounted on the vehicle C and the charge system 20A included in the vehicle C is determined.

FIG. 3 is a block diagram illustrating the internal configuration of the development support device 100 according to the first embodiment. The development support device 100 is a general-purpose or dedicated computer and includes a control unit 101, a storage unit 102, a communication unit 103, an operation unit 104, and a display unit 105.

The control unit 101 includes a CPU, a ROM, and a RAM. The CPU included in the control unit 101 expands various computer programs stored in the ROM or the storage unit 102 on the RAM and executes the programs to cause the entire apparatus to function as the determination device according to the present application.

The control unit 101 is not limited to the above configuration and may be any processing circuit or arithmetic circuit including a plurality of CPUs, multi-core CPUs, graphics processing units (GPUs), microcomputers, and volatile or nonvolatile memories. The control unit 101 may have functions such as a timer that measures the elapsed time from when a measurement start instruction is given to when a measurement end instruction is given, a counter that counts numbers, and a clock that outputs date and time information.

The storage unit 102 includes a storage device using a hard disk drive (HDD), a solid state drive (SSD), and the like. The storage unit 102 stores various computer programs executed by the control unit 101, data necessary for executing the computer programs, and the like. The computer program stored in the storage unit 102 includes a determination program PG1 that estimates the behavior of charge control for the energy storage device 10 using a battery model BM1 that simulates the energy storage device 10 and a charge system model CSM1 that simulates the charge system 20A on the vehicle side and determines the compatibility between the energy storage device 10 and the charge system 20A. The determination program PG1 may be a single computer program or a program group including a plurality of programs.

The computer program stored in the storage unit 102 is provided, for example, by a non-transitory recording medium M in which the computer program is recorded in a readable manner. The recording medium M is a portable memory such as a CD-ROM, a universal serial bus (USB) memory, a secure digital (SD) card, a micro SD card, and a compact flash (registered trademark). In this case, the control unit 101 reads a computer program from the recording medium M using a reading device (not illustrated) and installs the read computer program in the storage unit 102. Alternatively, the computer program stored in the storage unit 102 may be provided by communication via the communication unit 103. In this case, the control unit 101 may acquire the computer program via the communication unit 103 and install the acquired computer program in the storage unit 102.

The storage unit 102 stores various data in addition to the computer program. For example, the storage unit 102 stores the battery model BM1 that simulates the energy storage device 10 and the charge system model CSM1 that simulates the charge system 20A. The battery model BM1 includes, for example, an equivalent circuit representing the energy storage device 11. The storage unit 102 stores information regarding the circuit configuration of the equivalent circuit, a value of each element constituting the equivalent circuit, and the like. The battery model BM1 may further include a BMU model that simulates the operation of the BMU 12. The charge system model CSM1 is set using a transfer function representing the relationship between a control input and a control output in the charge system 20A. The storage unit 102 stores parameters and the like that describe a transfer function between a control input and a control output.

The storage unit 102 may include a battery table BT that stores information of the energy storage device 10 in association with an identifier for identifying the energy storage device 10. The battery information registered in the battery table BT includes, for example, the information of the positive electrode and the negative electrode, the information of the electrolyte solution, and the information on the tabs. The information of the positive electrode and the negative electrode is information such as the active material names, thicknesses, widths, depths, and open circuit potentials of the positive electrode and the negative electrode. The information of the electrolyte solution and the tabs is information such as ion species, transport number, diffusion coefficient, and conductivity. The information registered in the battery table BT may include the information of components and the like constituting the energy storage device 10. The information stored in the battery table BT is used as part of the parameters when the above-described simulation is executed.

The communication unit 103 includes a communication interface for communicating with an external device via a communication network (not illustrated). The external device is, for example, an information processing terminal such as a computer or smartphone used by the user. When information to be transmitted to the external device is input from the control unit 101, the communication unit 103 transmits the input information to the external device and outputs information from the external device received via the communication network to the control unit 101.

The communication unit 103 may be configured to be able to communicate with the BMU 12 included in the vehicle ECU 30 and the energy storage device 10. The control unit 101 may acquire information regarding the traveling state of the vehicle C, various measurement values measured by the energy storage device 10, and the like via the communication unit 103 and execute simulation based on the acquired information.

The operation unit 104 includes an input interface such as a keyboard, a mouse, and a touch panel and receives an operation by the user. The display unit 105 includes a liquid crystal display device and displays information to be notified to the user. In the embodiment, the development support device 100 includes the operation unit 104 and the display unit 105. However, the operation unit 104 and the display unit 105 are not essential and may be configured to receive an operation via a computer connected to the outside of development support device 100 and output information to be notified to the external computer.

The configuration of the simulation model will be described below.

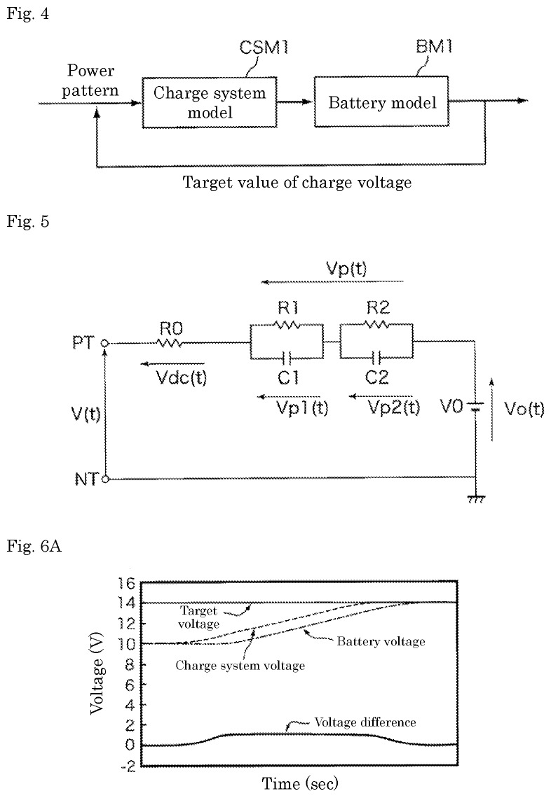

FIG. 4 is a block diagram illustrating the configuration of a simulation model used by the development support device 100. The development support device 100 estimates the behavior of charge control in the vehicle C by executing a simulation using the charge system model CSM1 that simulates the charge system 20A and the battery model BM1 that simulates the energy storage device 10.

A power pattern assuming the use of the vehicle C and the target value of the charge voltage set based on the estimation result of the battery model BM1 are input to the charge system model CSM1. In this case, the power pattern assuming the use of the vehicle C represents a temporal change in power when the vehicle C repeatedly starts, travels, and stops and is calculated from the difference between the power generated by the alternator 22 and the vehicle power consumption. The charge system model CSM1 sets this power pattern as a control input x(t) and calculates a control output y(t) based on the target value of the charge voltage. The control output y(t) represents, for example, a charge voltage supplied from the alternator 22 to the energy storage device 10.

In the embodiment, a transfer function G(s) is set between the control input x(t) and the control output y(t) in view of the occurrence of a control delay in the charge system 20A. The function form of the transfer function G(s) can be determined based on the actual measurement of a power pattern when the vehicle C is in use, a temporal change in power generated by the alternator 22, a temporal change in power consumed by the vehicle C, and the like. The transfer function G(s) preferably has a function form that simulates the slew rate of the control response in the charge system 20A.

When the transfer function G(s) is given, the control unit 101 of the development support device 100 calculates the control output y(t) for the control input x(t) of the charge system model CSM1 by the following procedure. First, the control unit 101 performs the Laplace transform of the control input x(t) to obtain a function X(s). The control unit 101 obtains output Y s)=G(s)X(s) obtained by multiplying the function X(s) by the transfer function G(s). The control unit 101 performs the inverse Laplace transform of the output Y(s) to obtain the control output y(t).

The battery model BM1 estimates the voltage (an open circuit voltage Vo) and the SOC of the energy storage device 11 when a charge voltage (that is, the control output y(t) of the charge system model CSM1) is applied. The battery model BM1 obtains the target value of the charge voltage based on the estimated SOC and feeds back the target value to the charge system model CSM1.

FIG. 5 is a circuit diagram illustrating an outline of the battery model BM1. The battery model BM1 includes an equivalent circuit of the energy storage device 11. The equivalent circuit of the energy storage device 11 is described by, for example, a resistance element R0, a first RC parallel circuit formed by connecting a resistance element R1 and a capacitance element C1 in parallel, a second RC parallel circuit formed by connecting a resistance element R2 and a capacitance element C2 in parallel, and a constant voltage source VO.

The resistance element R0 represents a DC resistance component (DC impedance) of the energy storage device 11. The DC resistance component of the energy storage device 11 corresponds to, for example, the resistance of the electrode of the energy storage device 11. The resistance value of the resistance element R0 is a value that changes depending on a discharge current, a charge voltage, an SOC, a temperature, and the like. When the resistance value of the resistance element R0 is determined, the voltage generated across the resistance element R0 when a current I(t) flows through the equivalent circuit can be calculated. The voltage generated across the resistance element R0 is defined as a DC resistance voltage Vdc(t).

The two RC parallel circuits are circuit elements for describing the transient polarization characteristics of the energy storage device 10. The respective values of the resistance element R1 and the capacitance element C1 constituting the first RC parallel circuit and the resistance element R2 and the capacitance element C2 constituting the second RC parallel circuit are given as values varying according to the SOC of the energy storage device 10. When these values are determined, impedances in the first RC parallel circuit and the second RC parallel circuit are determined. When the impedance is determined, the voltage (polarization voltage Vp(t)) generated in the first RC parallel circuit and the second RC parallel circuit when the current I(t) flows through the equivalent circuit can be calculated. The polarization voltage Vp(t) is the total voltage of a polarization voltage Vp1(t) generated in the first RC parallel circuit and a polarization voltage Vp2(t) generated in the second RC parallel circuit.

Assume that the time constant in the first RC parallel circuit is τ1, and the time constant in the second RC parallel circuit is τ2. The time constant τ1 is determined as a value obtained by multiplying the resistance value of the resistance element R1 and the capacitance value of the capacitance element C1 constituting the first RC parallel circuit. The time constant τ1 is reflected in a temporal change in the polarization voltage Vp1(t) generated in the first RC parallel circuit. Similarly, the time constant τ2 is determined as a value obtained by multiplying the resistance value of the resistance element R2 and the capacitance value of the capacitance element C2 constituting the second RC parallel circuit. The time constant τ2 is reflected in a temporal change in the polarization voltage Vp2(t) generated in the second RC parallel circuit. Changing the time constants τ1 and τ2 makes it possible to express various phenomena occurring in the energy storage device 11.

The constant voltage source VO is a voltage source that outputs a DC voltage. The voltage output from the constant voltage source VO represents an open circuit voltage (OCV) of the energy storage device 11 and is referred to as Vo(t). The open circuit voltage Vo(t) is given as a function of SOC, temperature, or the like.

A terminal voltage V(t) between a positive electrode terminal PT and a negative electrode terminal NT is given as follows, using the DC resistance voltage Vdc(t), the polarization voltage Vp(t), and the open circuit voltage Vo(t),

V(t)=Vdc(t)+Vp(t)+Vo(t).

The value of each element constituting the equivalent circuit is determined, for example, based on an actual measurement result in consideration of a relationship such as current and SOC.

The following shows simulation results using the charge system model CSM1 and the battery model BM1.

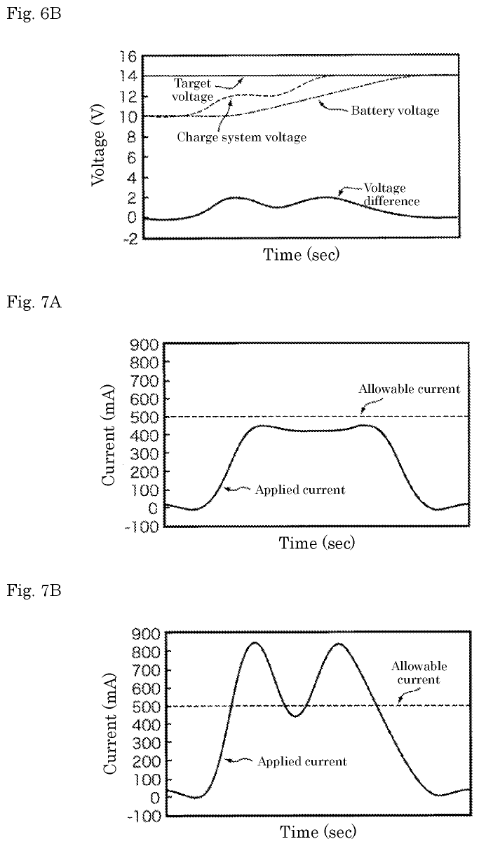

FIGS. 6A and 6B are graphs each illustrating a simulation result of a charge voltage and a battery voltage. FIG. 6A illustrates a simulation result in a case in which the slew rate of a control response in the charge system 20A is low, and FIG. 6B illustrates a simulation result in a case in which the slew rate of a control response in the charge system 20A is high. The horizontal axis of each graph represents time (sec), and the vertical axis represents voltage (V).

The simulation results in FIGS. 6A and 6B show the temporal change in the charge system voltage and the temporal change in the battery voltage when the energy storage device 10 is charged to the target voltage. In this case, the charge system voltage represents the voltage determined based on a control input (power pattern) in the charge system 20A. The battery voltage represents the terminal voltage (the terminal voltage V(t) illustrated in FIG. 5) of the energy storage device 10.

As can be seen from the voltage difference graph illustrated in FIG. 6A, when the slew rate of a control response is low, the difference between the charge system voltage and the battery voltage is relatively small. On the other hand, as can be seen from the voltage difference graph illustrated in FIG. 6B, when the slew rate of a control response is high, the difference between the charge system voltage and the battery voltage is relatively large.

FIGS. 7A and 7B are graphs each illustrating a simulation result of an applied current to the energy storage device 10. FIG. 7A illustrates a simulation result in a case in which the slew rate of a control response in the charge system 20A is low, and FIG. 7B illustrates a simulation result in a case in which the slew rate of a control response in the charge system 20A is high. The horizontal axis of each graph represents time (sec), and the vertical axis represents current (mA).

The simulation results in FIGS. 7A and 7B illustrate temporal changes in the current input to the energy storage device 10 when the energy storage device 10 is charged to the target voltage. Obviously from the simulation results in FIGS. 6A, 6B, 7A, and 7B, when the voltage difference between the charge system 20A and the energy storage device 10 increases, the amount of current entering the energy storage device 10 may become equal to or more than an allowable amount.

The control unit 101 of the development support device 100 determines the compatibility between the energy storage device 10 and the charge system 20A based on these simulation results. For example, the control unit 101 may set a determination threshold regarding the voltage difference between the charge system voltage and the battery voltage obtained as a simulation result and may determine compatibility between the energy storage device 10 and the charge system 20A based on the magnitude relationship between the calculated voltage difference and the determination threshold. In this case, the control unit 101 determines that the compatibility is not good when the calculated voltage difference is greater than or equal to the determination threshold and determines that the compatibility is good when the calculated voltage difference is less than the determination threshold.

The control unit 101 may compare the magnitudes of an applied current and an allowable current obtained as a simulation result and determine the compatibility between the energy storage device 10 and the charge system 20A based on the comparison result. In this case, the control unit 101 determines that the compatibility is not good when the applied current is greater than or equal to the allowable current and determines that the compatibility is good when the applied current is less than the allowable current.

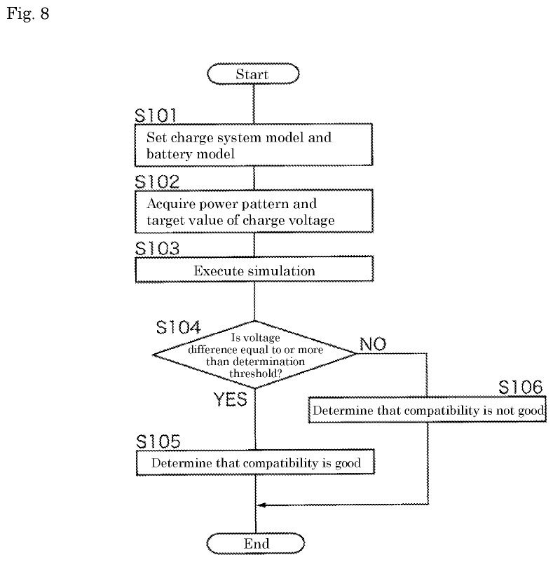

FIG. 8 is a flowchart illustrating a procedure of processing executed by the development support device 100. The control unit 101 of the development support device 100 sets the charge system model CSM1 that simulates the charge system 20A included in the vehicle C and the battery model BM1 that simulates the energy storage device 10 mounted on the vehicle C (step S101). At this time, the control unit 101 may set the transfer function G(s) used in the charge system model CSM1 and the value of each element constituting the equivalent circuit of the energy storage device 11. Alternatively, the transfer function G(s) and the value of each element may be set in advance. In this case, the control unit 101 may read the transfer function G(s) and the value of each element from the storage unit 102.

Next, the control unit 101 acquires a power pattern assuming the use of the vehicle C and the target value of the charge voltage (step S102). The power pattern assuming the use of the vehicle C represents a temporal change in power when the vehicle C repeats starting, traveling, and stopping. The power pattern is set in advance on the assumption that the vehicle C is in use. The target value of the charge voltage is, for example, the value set based on information such as SOC. In step S102, the target value (initial value) of the charge voltage may be set according to the power pattern to be used.

Next, the control unit 101 executes a simulation using the charge system model CSM1 and the battery model BM1 (step S103). By using the charge system model CSM1, the control unit 101 calculates a charge voltage (control output y(t)) representing a control response of the charge system 20A with respect to the control input x(t) according to the power pattern. The control unit 101 estimates the voltage (open circuit voltage Vo) and the SOC of the energy storage device 11 when a charge voltage is applied by using the battery model BM1. The control unit 101 obtains the target value of the charge voltage based on the estimated SOC, feeds back the target value to the charge system model CSM1, and sequentially estimates the charge voltage and the battery voltage at each time.

The control unit 101 then determines whether or not the voltage difference between the charge system voltage and the battery voltage is equal to or more than a determination threshold (step S104). Upon determining that the voltage difference is equal to or more than the determination threshold (S104: YES), the control unit 101 determines that the compatibility between the energy storage device 10 and the charge system 20A is good (step S105). In contrast to this, upon determining that the voltage difference is less than the determination threshold (S104: NO), the control unit 101 determines that the compatibility between the energy storage device 10 and the charge system 20A is not good (step S106).

In step S104 in the flowchart illustrated in FIG. 8, the compatibility between the energy storage device 10 and the charge system 20A is determined based on the voltage difference between the charge system voltage and the battery voltage. Alternatively, the magnitudes of an applied current to the energy storage device 10 and an allowable current obtained as a simulation result may be compared with each other to determine the compatibility between the energy storage device 10 and the charge system 20A based on the comparison result. Furthermore, the control unit 101 may be configured to estimate the time (charge time) required from the start of charging to the end of charging and determine the compatibility between the energy storage device 10 and the charge system 20A according to the lengths of the charge time and the threshold time.

As described above, in the first embodiment, the behavior of the charge control is estimated by executing the simulation using the battery model BM1 simulating the energy storage device 10 and the charge system model CSM1 simulating the charge system 20A, and the compatibility between the energy storage device 10 and the charge system 20A is determined based on the estimation result. Accordingly, it is not necessary to perform verification using actual machines or prototypes of the energy storage device 10 and the charge system 20A, and compatibility between the energy storage device 10 and the charge system 20A can be determined by simulation. As a result, the development support device 100 can determine the charge control specification of charge system 20A and the energy storage device 10 mounted on the vehicle C at an initial stage of product development.

The second embodiment will exemplify a case in which the present invention is applied to a charge system mounted on a vehicle such as a hybrid electric vehicle (HEV) or an electric vehicle (EV).

### Second Embodiment

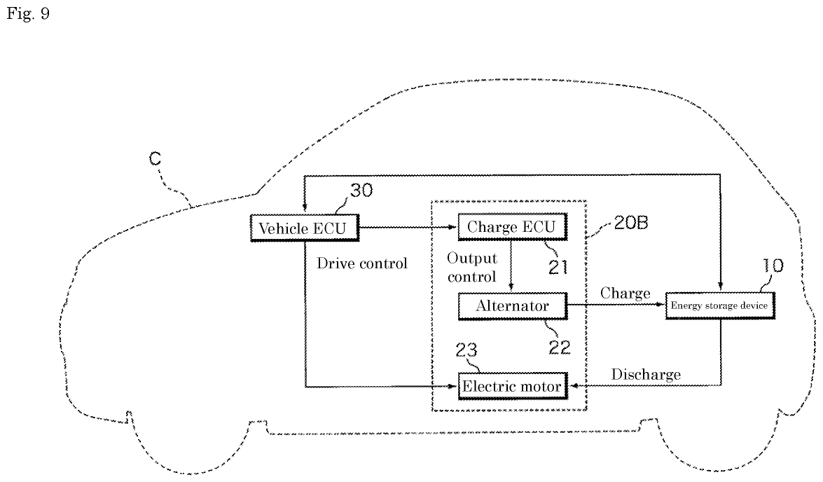

FIG. 9 is a block diagram illustrating the configuration of a control system in a vehicle. A vehicle C includes, as the components of a control system, an energy storage device 10, a charge-discharge system 20B for charging the energy storage device 10, and a vehicle ECU 30 that executes control of the entire vehicle. The energy storage device 10, the charge-discharge system 20B, and the vehicle ECU 30 are communicably connected to each other via an in-vehicle line such as CAN or LIN. Since the configurations of the energy storage device 10 and the vehicle ECU 30 are similar to those of the first embodiment, a description thereof will be omitted.

The charge-discharge system 20B includes a charge ECU 21, an alternator 22, and an electric motor 23 described in the first embodiment. The charge-discharge system 20B mounted on the vehicle C is developed and manufactured by, for example, a vehicle manufacturer, and the energy storage device 10 is developed and manufactured by, for example, a battery manufacturer. When the specification of the charge-discharge system 20B mounted on the vehicle C and the performance of the energy storage device 10 incorporated in the vehicle C do not match, there is a possibility that the performance of the battery cannot be sufficiently exerted or the deterioration of the battery is accelerated. In a case in which the above-described defect is found at a point of time when the energy storage device 10 is incorporated in the vehicle C and the entire vehicle is comprehensively verified, it is necessary to review the specification of the charge-discharge system 20B, or it is necessary to change the type of the energy storage device 10 incorporated in the vehicle C. Therefore, the agreement of the specification cannot be reached at an early stage.

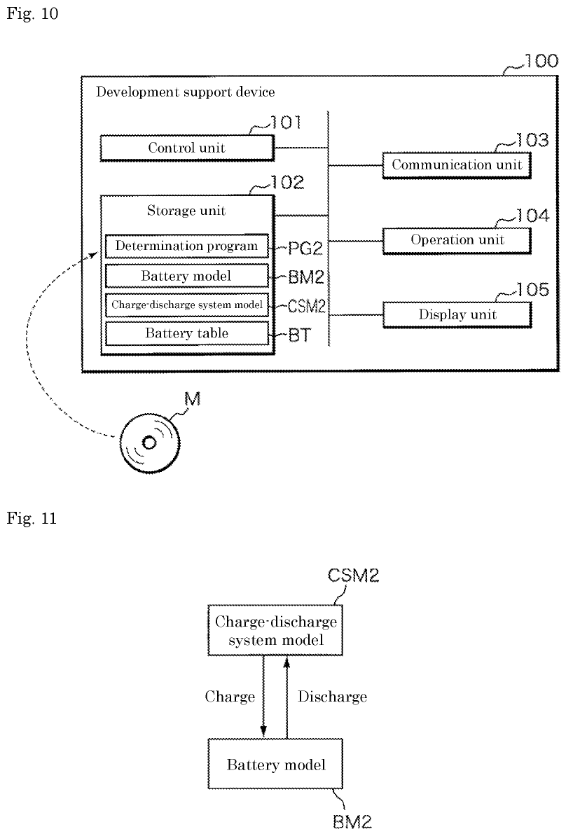

According to the embodiment, in a computer (a development support device 100 illustrated in FIG. 10) independent of the vehicle C, a simulation using a model simulating the energy storage device 10 and a model simulating the charge-discharge system 20B of the vehicle C is executed, and the compatibility between the energy storage device 10 mounted on the vehicle C and the charge-discharge system 20B included in the vehicle C is determined.

FIG. 10 is a block diagram illustrating the internal configuration of the development support device 100 according to the second embodiment. The development support device 100 is a general-purpose or dedicated computer and includes a control unit 101, a storage unit 102, a communication unit 103, an operation unit 104, and a display unit 105. Since these configurations are similar to those of the first embodiment, a description thereof will be omitted.

The storage unit 102 included in the development support device 100 stores various computer programs executed by the control unit 101, data necessary for executing the computer programs, and the like. The computer program stored in the storage unit 102 includes a determination program PG2 that estimates the behavior of charge control for the energy storage device 10 using a battery model BM2 that simulates the energy storage device 10 and a charge-discharge system model CSM2 that simulates the charge-discharge system 20B on the vehicle side and determines the compatibility between the energy storage device 10 and the charge-discharge system 20B. The determination program PG2 may be a single computer program or a program group including a plurality of programs.

The computer program stored in the storage unit 102 is provided, for example, by a non-transitory recording medium M in which the computer program is recorded in a readable manner. Alternatively, the computer program stored in the storage unit 102 is provided by communication via the communication unit 103.

The storage unit 102 stores various data in addition to the computer program. For example, the storage unit 102 stores the battery model BM2 that simulates the energy storage device 10. The battery model BM2 includes, for example, an equivalent circuit representing an energy storage device 11. The storage unit 102 stores information regarding the circuit configuration of the equivalent circuit, a value of each element constituting the equivalent circuit, and the like. The battery model BM2 may further include a model that simulates components included in the energy storage device 10, such as a BMU 12, a current sensor 13, a current sensor 13, a voltage sensor 14, a temperature sensor 15, and a relay 16. The battery model BM2 may further include a model simulating control executed by the energy storage device 10 and a model simulating events such as the deterioration and heat generation of the energy storage device 10.

The storage unit 102 stores the charge-discharge system model CSM2 that simulates the charge-discharge system 20B in the vehicle C. The charge-discharge system model CSM2 is described using control parameters including the efficiency, resistance, rotational speed, predetermined voltage, and voltage control measurement of the charge-discharge device (in the embodiment, the alternator 22 and the electric motor 23).

The storage unit 102 may include a battery table BT that stores information of the energy storage device 10 in association with an identifier for identifying the energy storage device 10. The battery information registered in the battery table BT is similar to the information described in the first embodiment. The information stored in the battery table BT is used as part of the parameters when the above-described simulation is executed.

The configuration of the simulation model will be described below.

FIG. 11 is a block diagram illustrating the configuration of a simulation model used by the development support device 100. The development support device 100 estimates the state of the energy storage device 10 by executing a simulation using the battery model BM2 that simulates the energy storage device 10 and the charge/discharge system model CSM2 that simulates the charge-discharge system 20B.

The battery model BM2 includes the SOC, SOH, temperature, and current of the energy storage device 10 as parameters. The charge-discharge system model CSM2 includes, as parameters, the efficiency, resistance, rotational speed, predetermined voltage, and voltage control characteristics of the charge-discharge device. The parameters of the battery model BM2 and the charge-discharge system model CSM2 in the initial state are set by the user.

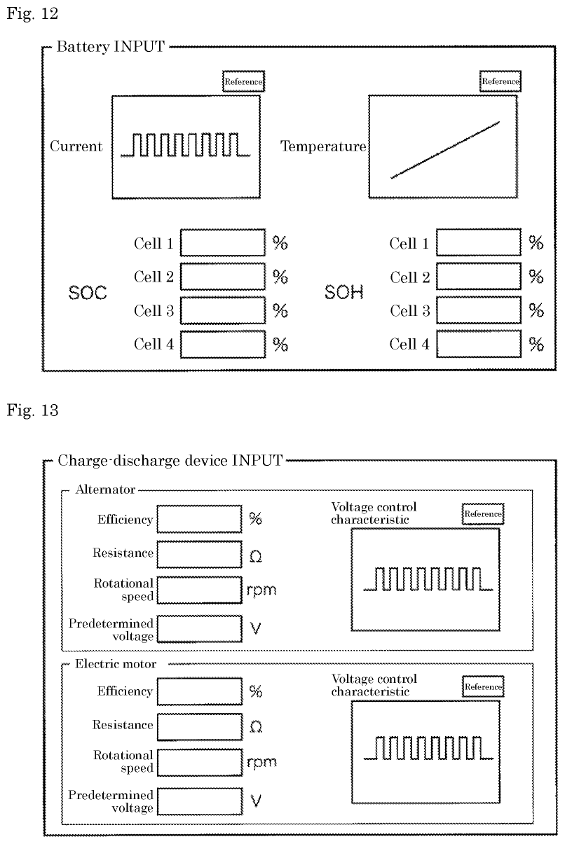

FIG. 12 is a schematic diagram illustrating an example of a parameter setting screen in the battery model BM2. When executing a simulation, the control unit 101 of the development support device 100 generates screen data as illustrated in FIG. 12 and displays the screen data on the display unit 105. The user inputs the initial states of the current, temperature, SOC, and SOH of the energy storage device 10 using the operation unit 104. Regarding the current and the temperature, respective temporal changes are set. The user may prepare files of graphs indicating temporal changes in current and temperature in advance and select a desired file via a file selection screen (not illustrated) presented when a reference button is pressed. The user may directly draw a graph indicating temporal changes in current and temperature in an input field. Regarding SOC and SOH, numerical values are set via the operation unit 104. When the energy storage device 11 includes, for example, four cells, an SOC and an SOH may be set for each cell.

FIG. 13 is a schematic diagram illustrating an example of a parameter setting screen in the charge-discharge system model CSM2. When executing a simulation, the control unit 101 of the development support device 100 generates screen data as illustrated in FIG. 13 and displays the screen data on the display unit 105. The user uses the operation unit 104 to input the initial states of the efficiency, resistance, rotational speed, predetermined voltage, and voltage control characteristics of the alternator 22 and the electric motor 23. Regarding efficiency, resistance, rotation speed, and predetermined voltage, numerical values are set via the operation unit 104. As for the voltage control characteristic, a temporal change in voltage is set. The user may prepare files of graphs indicating a temporal change in voltage in advance and select a desired file via a file selection screen (not illustrated) presented when a reference button is pressed. The user may directly draw a graph indicating a temporal change in voltage in an input field.

In the embodiment, the parameter setting screens of the battery model BM2 and the charge-discharge system model CSM2 are individually prepared. However, the two screens may be integrated into a parameter setting screen.

Processing executed by the development support device 100 will be described below.

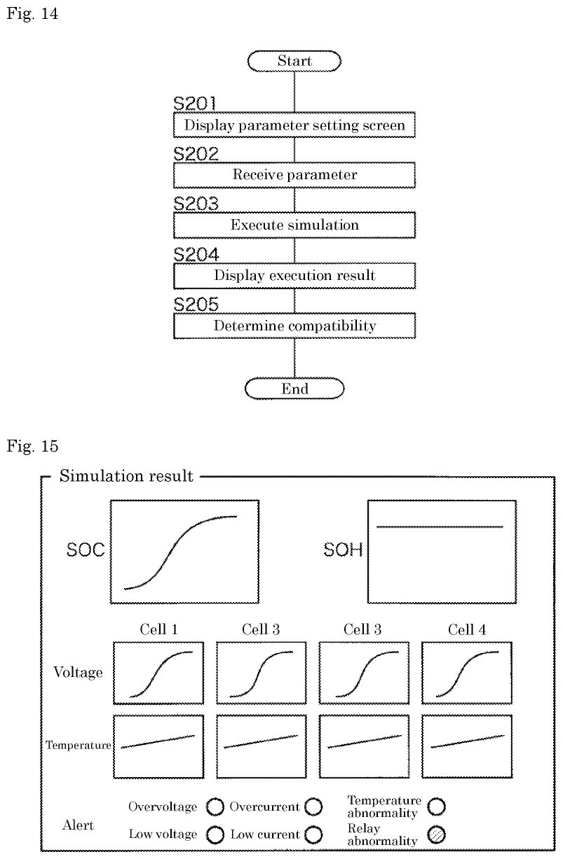

FIG. 14 is a flowchart illustrating a procedure of processing executed by the development support device 100. In order to receive the parameters in the initial state, the control unit 101 of development support device 100 displays a parameter setting screen as illustrated in FIGS. 12 and 13 on the display unit 105 (step S201). The control unit 101 receives the input of parameters via the displayed parameter setting screen (step S202).

The control unit 101 sets the received parameters to the initial state and executes a simulation using the battery model BM2 and the charge-discharge system model CSM2 (step S203). The control unit 101 is only required to simulate the behavior of the energy storage device 10 when the efficiency, resistance, rotational speed, predetermined voltage, and voltage control characteristics of the alternator 22 and the electric motor 23 are set. A known method is used as a simulation method. For example, the control unit 101 can estimate the SOC, SOH, cell voltage, and cell temperature of the energy storage device 11 by executing a simulation using an equivalent circuit of the energy storage device 11. The open/close state of the relay 16 can be estimated by simulating the operation of the BMU 12.

The control unit 101 displays the simulation execution result on the display unit 105 (step S204). FIG. 15 is a schematic diagram illustrating a display example of a simulation execution result. For example, the control unit 101 displays temporal changes in the SOC, SOH, voltage, and temperature of the energy storage device 11 as graphs as simulation execution results. In the example in FIG. 15, the voltage and temperature of the energy storage device 11 are displayed for each cell. The control unit 101 may display an alert when an overvoltage, low voltage, overcurrent, low current, or temperature abnormality is detected in the energy storage device 11 or when a relay abnormality in which the relay 16 is always in the open state is detected by simulation. In the example in FIG. 15, the control unit 101 turns on the alarm lamp to present the occurrence of the abnormality to the user.

The control unit 101 determines the compatibility between the energy storage device 10 and the charge-discharge system 20B based on the simulation execution result (step S205). As a result of executing the simulation, the control unit 101 determines that the compatibility between the energy storage device 10 and the charge-discharge system 20B is not good when a battery abnormality such as an overvoltage, low voltage, overcurrent, or low current abnormality occurs, when a temperature abnormality occurs, when a relay abnormality occurs in which the relay 16 is always in the open state, or the like. On the other hand, when these abnormalities do not occur, the control unit 101 determines that the compatibility between the energy storage device 10 and the charge-discharge system 20B is good.

As described above, in the second embodiment, the behavior of the energy storage device is estimated by executing the simulation using the battery model BM2 simulating the energy storage device 10 and the charge-discharge system model CSM2 simulating the charge-discharge system 20B, and the compatibility between the energy storage device 10 and the charge-discharge system 20B is determined based on the estimation result. Accordingly, it is not necessary to perform verification using actual machines or prototypes of the energy storage device 10 and the charge-discharge system 20B, and compatibility between the energy storage device 10 and the charge-discharge system 20B can be determined by simulation. As a result, the development support device 100 can determine the charge-discharge system 20B and the energy storage device mounted on the vehicle C at an initial stage of product development.

It is to be understood that the embodiments disclosed herein are illustrative in all respects and not restrictive. The scope of the present invention is defined not by the meanings described above but by the claims and is intended to include meanings equivalent to the claims and all modifications within the scope.

For example, in the embodiment, as described above, the energy storage device 10 is a power source for a vehicle. The vehicle is not limited to a four-wheeled vehicle and may be a two-wheeled vehicle. Alternatively, the vehicle may be a train or a moving object such as an automatic guided vehicle (AGV), an unmanned flying object (drone), or an aircraft. The energy storage device 10 may be a high-voltage power source (several hundred V) for driving the vehicle, an auxiliary battery (12 V or 24 V) that supplies power other than for driving, an engine starting battery (12 V or 24 V), or a mild hybrid battery (48 V). Examples of the vehicle charge system include, but are not limited to, regenerative power recovered at the time of deceleration of the vehicle, solar power generation mounted on a roof or the like, a 100 V power source or a 200 V quick charger for parking and charging, and an energy storage system incorporating a reused battery. The energy storage device 10 may be a power source for electronic equipment or a power source for energy storage. In these cases, the development support device 100 may determine the compatibility between the charge system and the energy storage device included in electronic equipment or energy storage facilities.

The present embodiment has exemplified the configuration of the energy storage device 11 including the plurality of lithium ion secondary batteries. Alternatively, the energy storage device 10 may be a module in which a plurality of cells are connected, a bank in which a plurality of modules are connected, a domain in which a plurality of banks are connected, or the like. Instead of the lithium ion secondary battery, any battery such as an all-solid-state lithium ion battery, a zinc-air battery, a sodium ion battery, or a lead-acid battery may be adopted.

1. A computer program for causing a computer to execute a process of:
estimating a state of at least one of an energy storage device and a charge system by executing a simulation using a battery model for simulating the energy storage device and a charge system model for simulating the charge system that charges the energy storage device; and
determining compatibility between the energy storage device and the charge system based on the estimated state.

2. The computer program according to claim 1, wherein
the state estimated by the simulation includes a temporal change in charge system voltage determined according to the state of the energy storage device and a temporal change in battery voltage that is a voltage across both terminals of the energy storage device, and
the computer is caused to execute the process of determining compatibility between the energy storage device and the charge system based on a difference between the charge system voltage and the battery voltage.

3. The computer program according to claim 1, wherein
the state estimated by the simulation includes a temporal change in applied current applied to the energy storage device at the time of charging, and
the computer is caused to execute the process of determining compatibility between the energy storage device and the charge system based on a difference between the applied current and an allowable value set for the applied current.

4. The computer program according to claim 1, wherein the charge system model is set using a transfer function representing a relationship between a control input and a control output in the charge system.

5. The computer program according to claim 1, wherein the charge system model simulates a control delay in the charge system.

6. The computer program according to claim 1, wherein the battery model includes an equivalent circuit of the energy storage device.

7. A computer program for causing a computer to execute a process of:
estimating a state of at least one of an energy storage device and a power management system by executing a simulation using a battery model for simulating the energy storage device and a charge-discharge system model for simulating a power management system for the energy storage device; and
determining compatibility between the energy storage device and the power management system based on the estimated state of the energy storage device.

8. The computer program according to claim 7, wherein the battery model includes a state estimation model for estimating at least one of an SOC, SOH, voltage, current, and temperature of the energy storage device, a component model for simulating a component constituting the energy storage device, a charge-discharge control model for simulating charge-discharge control for the energy storage device, and an event estimation model for estimating at least one of deterioration and heat generation of the energy storage device.

9. The computer program according to claim 7, wherein the charge-discharge system model is a model including at least one of efficiency, resistance, a rotational speed, a predetermined voltage, and a voltage control characteristic in the power management system as a parameter.

10. The computer program according to claim 7, wherein the computer is caused to execute a process of receiving an input of a parameter indicating an initial state of each model.

11. The computer program according to claim 7, wherein the computer is caused to execute a process of causing a display device to display an estimation result obtained by each model.

12. A determination device comprising:
an estimation unit that estimates a state of at least one of an energy storage device and a charge system by executing a simulation using a battery model for simulating the energy storage device and a charge system model for simulating a charge system that charges the energy storage device; and
a determination unit that determines compatibility between the energy storage device and the charge system based on the estimated state.

13. A determination device comprising:
an estimation unit that estimates a state of at least one of an energy storage device and a power management system by executing a simulation using a battery model for simulating the energy storage device and a charge-discharge system model for simulating the power management system for the energy storage device; and
a determination unit that determines compatibility between the energy storage device and the power management system based on the estimated state of the energy storage device.

14. (canceled)

15. (canceled)

16. The computer program according to claim 2, wherein
the state estimated by the simulation includes a temporal change in applied current applied to the energy storage device at the time of charging, and
the computer is caused to execute the process of determining compatibility between the energy storage device and the charge system based on a difference between the applied current and an allowable value set for the applied current.

17. The computer program according to claim 8, wherein the charge-discharge system model is a model including at least one of efficiency, resistance, a rotational speed, a predetermined voltage, and a voltage control characteristic in the power management system as a parameter.
